(19) United States
(12) Patent Application Publication
(10) Pub. No.: US 2025/0380498 A1
(43) Pub. Date: Dec. 11, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Sangjine Park, Suwon-si (KR); Ilyoung Yoon, Suwon-si (KR)

(21) Appl. No.: 19/006,400

(22) Filed: Dec. 31, 2024

(30) Foreign Application Priority Data
Jun. 7, 2024 (KR) 10-2024-0074443

(51) Int. Cl. H10D 84/83; H10D 30/01; H10D 30/43; H10D 30/67; H10D 62/10; H10D 80/20; H10D 84/01; H10D 88/00

(52) U.S. Cl. CPC H10D 84/832; H10D 30/014; H10D 30/43; H10D 30/6735; H10D 30/6757; H10D 84/0128; H10D 62/121; H10D 80/251; H10D 88/01

(57) ABSTRACT

A semiconductor device according to various embodiments includes a substrate and a plurality of transistor stacks formed on the substrate. Each of the transistor stacks includes a lower transistor including at least one lower channel layer and a lower gate structure enclosing the at least one lower channel layer and formed on the substrate, and an upper transistor including at least one upper channel layer and an upper gate structure enclosing the at least one upper channel layer and formed on the lower transistor. A sum of a number of first lower channel layers and a number of first upper channel layers of a first transistor stack is different from a sum of a number of second lower channel layers and a number of second upper channel layers of a second transistor stack.

### CROSS-REFERENCE TO RELATED APPLICATION(S)

This application claims the benefit under 35 U.S.C. § 119 (a) of Korean Patent Application No. 10-2024-0074443, filed on Jun. 7, 2024, in the Korean Intellectual Property Office, the entire contents of which are incorporated herein by reference for all purposes.

### BACKGROUND

### 1. Field

The following description relates to a semiconductor device and a method of manufacturing the semiconductor device, and more specifically, relates to a three-dimensional (3D)-stacked or multi-stack semiconductor device including a transistor disposed on an upper part and a transistor disposed on a lower part and a manufacturing method thereof.

### 2. Description of Related Art

A transistor with a reduced size has been demanded to enhance the density of a logic element in an integrated circuit (IC). A semiconductor device having a multi-stack structure in which transistors are formed on lower and upper stacks has been developed to increase the density of transistors in a limited space on a substrate. The above information may be presented as related art to help with the understanding of the disclosure. No arguments or decisions are made as to whether any of the above is applicable as a prior art related to the disclosure.

### SUMMARY

A technical goal to be achieved through the present disclosure is to provide a semiconductor device with enhanced performance and speed and a manufacturing method of the semiconductor device.

However, the goals to be achieved through the present disclosure are not limited to those described above, and additional goals not mentioned above may be clearly understood by one of ordinary skill in the art from the following description.

A semiconductor device according to various embodiments includes a substrate, and a plurality of transistor stacks formed on the substrate. Each of the transistor stacks includes a lower transistor including at least one lower channel layer and a lower gate structure enclosing the at least one lower channel layer and formed on the substrate, and an upper transistor including at least one upper channel layer and an upper gate structure enclosing the at least one upper channel layer and formed on the lower transistor. A sum of a number of first lower channel layers and a number of first upper channel layers of a first transistor stack is different from a sum of a number of second lower channel layers and a number of second upper channel layers of a second transistor stack.

The number of the first lower channel layers is the same as the number of the second lower channel layers, and the number of the first upper channel layers is different from the number of the second upper channel layers.

The number of the first upper channel layers is the same as the number of the second upper channel layers, and the number of the first lower channel layers is different from the number of the second lower channel layers.

The sum of the number of the first lower channel layers and the number of the first upper channel layers of the first transistor stack is greater than the sum of the number of the second lower channel layers and the number of the second upper channel layers of the second transistor stack.

The semiconductor device further includes a third transistor stack. A sum of a number of third lower channel layers and a number of third upper channel layers of the third transistor stack is the same as the sum of the number of the second lower channel layers and the number of the second upper channel layers of the second transistor stack.

The number of the third upper channel layers is different from the number of the second upper channel layers and the number of the third lower channel layers is different from the number of the second lower channel layers.

A second upper transistor of the second transistor stack includes a first slit that removes a portion of a second upper gate structure. A third lower transistor of the third transistor stack includes a second slit that removes a portion of a third lower gate structure. A portion of channel layers disposed in a gate structure is removed by the first slit or the second slit.

The number of the second upper channel layers is one and the number of the second lower channel layers is two, and the number of the third upper channel layers is two and the number of the third lower channel layers is one.

An inside of the first slit or the second slit is filled with an insulating material.

A width of a channel layer of the first transistor stack, a width of a channel layer of the second transistor stack, and a width of a channel layer of the third transistor stack are the same as or different from each other.

Upper transistors of the first transistor stack, the second transistor stack, and the third transistor stack are n-channel metal oxide semiconductor (NMOS) transistors. Lower transistors of the first transistor stack, the second transistor stack, and the third transistor stack are p-channel metal oxide semiconductor (PMOS) transistors.

The semiconductor device further includes a plurality of lower source/drain structures respectively disposed on both ends of the lower transistors of the first transistor stack, the second transistor stack, and the third transistor stack.

The semiconductor device further includes a plurality of upper source/drain structures respectively disposed on both ends of the upper transistors of the first transistor stack, the second transistor stack, and the third transistor stack.

The number of the second upper channel layers is one, and the number of the second lower channel layers is three. The number of the third upper channel layers is three, and the number of the third lower channel layers is one.

The number of the second upper channel layers is two and the number of the second lower channel layers is three. The number of the third upper channel layers is three, and the number of the third lower channel layers is two.

The number of the second upper channel layers is two and the number of the second lower channel layers is four. The number of the third upper channel layers is four, and the number of the third lower channel layers is two.

According to various embodiments, a method of manufacturing a semiconductor device includes forming a plurality of transistor stacks including a lower transistor including at least one lower channel layer and a lower gate structure enclosing the at least one lower channel layer and an upper transistor including at least one upper channel layer and an upper gate structure enclosing the at least one upper channel layer, forming an upper source/drain structure or a lower source/drain structure between the transistor stacks spaced apart from each other, forming a first slit that removes a portion of a second upper gate structure of a second upper transistor of a second transistor stack, filling an inside of the first slit with an insulating material, and forming a gate contact or a source/drain contact respectively connected to the upper gate structure or the upper source/drain structure.

The forming of the first slit includes removing a portion of channel layers disposed in the second upper gate structure by the first slit.

The method further includes disposing a carrier on a top surface of the plurality of transistor stacks, flipping the plurality of transistor stacks, forming a second slit that removes a portion of a third lower gate structure of a third lower transistor of a third transistor stack, filling an inside of the second slit with an insulating material, and forming a gate contact or a source/drain contact respectively connected to the lower gate structure or the lower source/drain structure.

The forming of the second slit includes removing a portion of channel layers disposed in the third lower gate structure by the second slit.

The method further includes flipping the plurality of transistor stacks again, and removing the carrier disposed on the top surface of the plurality of transistor stacks.

The semiconductor device and the method of manufacturing the semiconductor device according to the present disclosure may implement the optimal performance or optimal speed for each individual transistor stack by including a plurality of transistor stacks configuring the semiconductor device and varying sums of the numbers of channel layers disposed in each transistor stack to be different from each other.

The semiconductor device and the method of manufacturing the semiconductor device according to the present disclosure may implement the optimal performance or optimal speed by setting the number of channel layers disposed in the transistor differently to suit the characteristics of an element for each individual transistor stack configuring the semiconductor device.

The effects according to the disclosure are not limited to the above-mentioned effects, and other unmentioned effects can be clearly understood from the following description by one of ordinary skill in the art.

### BRIEF DESCRIPTION OF THE DRAWINGS

FIG. 1 is a perspective view of a semiconductor device according to an example embodiment of the present disclosure.

FIG. 2 illustrates a schematic circuit diagram of an inverter circuit formed by the semiconductor device of FIG. 1.

FIG. 3A is a cross-sectional view taken along line I-I′ of FIG. 1 and is a cross-sectional view of a first transistor stack of a semiconductor device according to an example embodiment.

FIG. 3B is a cross-sectional view taken along line J-J′ of FIG. 1 and is a cross-sectional view of a second transistor stack of a semiconductor device according to an example embodiment.

FIG. 3C is a cross-sectional view taken along line K-K′ of FIG. 1 and is a cross-sectional view of a third transistor stack of a semiconductor device according to an example embodiment.

FIG. 4A is a cross-sectional view taken along line I-I′ of FIG. 1 and is a cross-sectional view of a first transistor stack of a semiconductor device according to another example embodiment.

FIG. 4B is a cross-sectional view taken along line J-J′ of FIG. 1 and is a cross-sectional view of a second transistor stack of a semiconductor device according to another example embodiment.

FIG. 4C is a cross-sectional view taken along line K-K′ of FIG. 1 and is a cross-sectional view of a third transistor stack of a semiconductor device according to another example embodiment.

FIG. 5A is a cross-sectional view taken along line I-I′ of FIG. 1 and is a cross-sectional view of a first transistor stack of a semiconductor device according to another example embodiment.

FIG. 5B is a cross-sectional view taken along line J-J′ of FIG. 1 and is a cross-sectional view of a second transistor stack of a semiconductor device according to another example embodiment.

FIG. 5C is a cross-sectional view taken along line K-K′ of FIG. 1 and is a cross-sectional view of a third transistor stack of a semiconductor device according to another example embodiment.

FIG. 6A is a cross-sectional view taken along line I-I′ of FIG. 1 and is a cross-sectional view of a first transistor stack of a semiconductor device according to another example embodiment.

FIG. 6B is a cross-sectional view taken along line J-J′ of FIG. 1 and is a cross-sectional view of a second transistor stack of a semiconductor device according to another example embodiment.

FIG. 6C is a cross-sectional view taken along line K-K′ of FIG. 1 and is a cross-sectional view of a third transistor stack of a semiconductor device according to another example embodiment.

FIG. 7 is a flowchart of a method of manufacturing a semiconductor device according to an example embodiment of the present disclosure.

FIGS. 8 to 27 illustrate a manufacturing process of a semiconductor device according to an example embodiment of the present disclosure.

FIGS. 28 to 31 illustrate a portion of a manufacturing process of a semiconductor device according to another example embodiment.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

Hereinafter, embodiments will be described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like constituent elements and a repeated description related thereto will not be repeated. In the description of embodiments, detailed description of well-known related structures or functions will not be repeated when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. In addition, in certain cases, even if a term is not described using “first,” “second,” etc., in the specification, it may still be referred to as “first” or “second” in a claim in order to distinguish different claimed elements from each other.

The same name may be used to describe an element included in the embodiments described above and an element having a common function. Unless otherwise mentioned, the descriptions on the embodiments may be applicable to the following embodiments and thus, duplicated descriptions will not be repeated for conciseness.

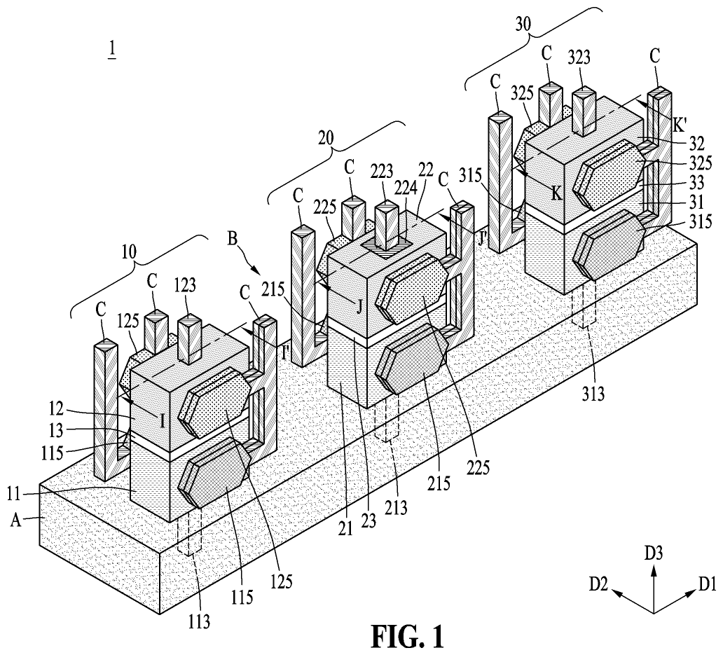

FIG. 1 is a perspective view of a semiconductor device according to an example embodiment of the present disclosure.

Referring to FIG. 1, a semiconductor device 1 according to various embodiments of the present disclosure may include a substrate A and a plurality of transistor stacks 10, 20, and 30 formed on the substrate A. The transistor stacks 10, 20, and 30 may include lower transistors 11, 21, and 31 formed on the substrate A and upper transistors 12, 22, and 32 formed on the lower transistors 11, 21, and 31, respectively.

The embodiment illustrates that the transistor stacks 10, 20, and 30 are arranged in a line in a first direction D1, but the embodiment is not limited thereto, and additional transistor stacks may be arranged in a line in a second direction.

The first direction D1 and a second direction D2 may be directions perpendicular to each other and parallel to the top surface of the substrate A. A third direction D3 may be a direction perpendicular to the first direction D1 and the second direction D2.

The substrate A may be a bulk substrate formed of a semiconductor material, such as a silicon (Si), silicon-germanium (SiGe), or silicon-on-insulator (SOI) substrate. Alternatively, the substrate A may be an insulating substrate including an insulating material. The insulating substrate may include at least one of silicon oxide, silicon nitride, silicon oxynitride, and silicon carbide. However, the example is not limited thereto.

The lower transistors 11, 21, and 31 of the first transistor stack 10, the second transistor stack 20, and the third transistor stack 30, respectively, may be p-channel metal-oxide semiconductor (PMOS) transistors.

A plurality of lower source/drain structures 115, 215, and 315 may be disposed on both ends of the lower transistors 11, 21, and 31 of the first to third transistor stacks 10, 20, and 30, respectively. The lower source/drain structures 115, 215, and 315 may be formed of silicon-germanium (SiGe) or silicon (Si) doped with p-type impurities, such as boron and/or gallium.

The upper transistors 12, 22, 32 of the first to third transistor stacks 10, 20, and 30 may be n-channel metal oxide semiconductor (NMOS) transistors.

A plurality of upper source/drain structures 125, 225, and 325 may be disposed on both ends of the upper transistors 12, 22, and 32 of the first to third transistor stacks 10, 20, and 30, respectively. The upper source/drain structures 125, 225, and 325 may be formed of silicon (Si) and may be doped with n-type impurities, such as phosphorus and/or arsenic.

However, the example is not limited thereto. The lower transistors 11, 21, and 31 may be NMOS transistors and the upper transistors 12, 22, and 32 may be PMOS transistors. In such embodiments, the lower source/drain structures 115, 215, and 315 may be formed of silicon (Si) and may be doped with n-type impurities, such as phosphorus and/or arsenic. The upper source/drain structures 125, 225, and 325 may be formed of silicon-germanium (SiGe) or silicon (Si) doped with p-type impurities, such as boron and/or gallium.

A source/drain contact C may be connected to each of the lower source/drain structures 115, 215, and 315 and/or each of the upper source/drain structures 125, 225, and 325. Each source/drain contact C may connect the upper transistor and the lower transistor to a power source and/or other circuit elements via one or more back-end-of-line (BEOL) elements, such as metal patterns (not shown), or one or more middle-of-line (MOL) elements, such as via structures (not shown) formed on the semiconductor device 1.

Each source/drain contact C may be formed of an electrically conductive material, for example, cobalt (Co), tungsten (W), ruthenium (Ru), or a combination thereof, such as a conductive metal material, but the example is not limited thereto. The source/drain contact C may be formed through direct and/or wet etching, such as reactive ion etch (RIE), and deposition, such as chemical vapor deposition (CVD) and plasma-enhanced CVD (PECVD). However, the example is not limited thereto.

A first lower gate contact 113, a second lower gate contact 213, and a third lower gate contact 313 may be connected to the lower transistors 11, 21, and 31 of the first to third transistor stacks 10, 20, and 30, respectively.

A first upper gate contact 123, a second upper gate contact 223, and a third upper gate contact 323 may be connected to the upper transistors 12, 22, and 32 of the first to third transistor stacks 10, 20, and 30, respectively. The gate contact may receive and transmit a gate input signal to a gate structure or may connect the gate structure to another circuit element.

Each gate contact may be formed of an electrically conductive material, for example, cobalt (Co), tungsten (W), ruthenium (Ru), or a combination thereof, such as a conductive metal material, but the example is not limited thereto. The gate contact may be formed through direct and/or wet etching, such as RIE, and deposition, such as CVD and PECVD. However, the example is not limited thereto.

Intermediate insulating layers 13, 23, and 33 may be disposed between the lower transistors 11, 21, and 31, and the upper transistors 12, 22, and 32, respectively. The lower transistors 11, 21, and 31, and the upper transistors 12, 22, and 32 may be separated from each other by the intermediate insulating layers 13, 23, and 33, respectively.

The intermediate insulating layers 13, 23, and 33 may be formed of, for example, silicon oxide (SiO), silicon nitride (SiN), and/or silicon oxynitride (SiON), but the example is not limited thereto. An upper gate structure of the upper transistors 12, 22, and 32 and a lower gate structure of the lower transistors 11, 21, and 31 may be electrically connected to each other through a separate structure that is not illustrated.

The semiconductor device 1 may include an interlayer dielectric B filled between the transistor stacks 10, 20, and 30 to insulate the transistor stacks 10, 20, and 30 from each other. The interlayer dielectric B may be formed of silicon oxide (SiO), silicon nitride (SiN), and/or silicon oxynitride (SiON), but the example is not limited thereto.

The semiconductor device 1 may include a power line (not shown) and a signal line (not shown) other than the components described above.

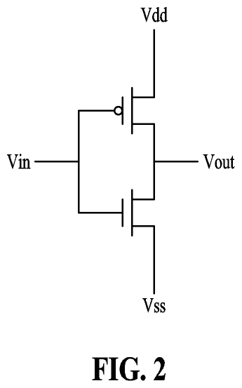

FIG. 2 illustrates a schematic circuit diagram of an inverter circuit formed by the semiconductor device of FIG. 1.

Referring to FIG. 2, the semiconductor device 1 may form an inverter circuit of a circuit diagram shown in FIG. 2. The inverter circuit may include a PMOS and an NMOS connected in series. Source nodes of the PMOS or NMOS may be connected to a positive voltage source Vdd or a negative voltage source Vss, respectively, to connect the inverter circuit to a power source and other circuit elements. Drain nodes of the PMOS or NMOS may be merged to be connected to other circuit elements based on a common gate input signal. The PMOS or NMOS may be formed by the lower transistors 11, 21, and 31 or the upper transistors 12, 22, and 32 shown in FIG. 1.

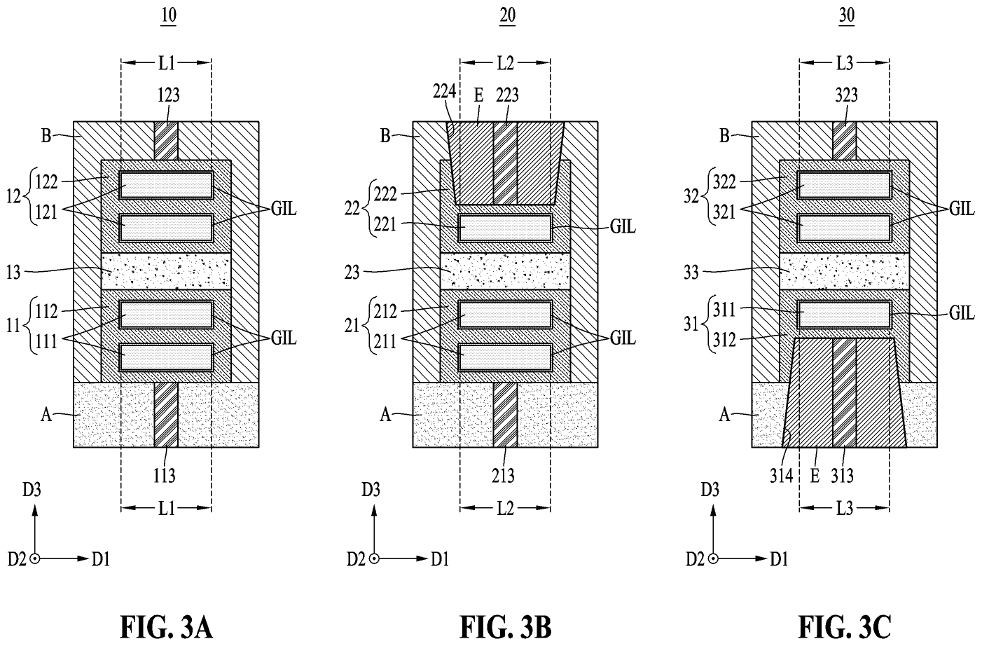

FIG. 3A is a cross-sectional view taken along line I-I′ of FIG. 1 and is a cross-sectional view of a first transistor stack of a semiconductor device according to an example embodiment. FIG. 3B is a cross-sectional view taken along line J-J′ of FIG. 1 and is a cross-sectional view of a second transistor stack of a semiconductor device according to an example embodiment.

FIG. 3C is a cross-sectional view taken along line K-K′ of FIG. 1 and is a cross-sectional view of a third transistor stack of a semiconductor device according to an example embodiment.

Referring to FIGS. 3A to 3C, the lower transistors 11, 21, and 31 formed on the substrate A may include one or more lower channel layers 111, 211, and 311, respectively, and lower gate structures 112, 212, and 312 enclosing the one or more lower channel layers 111, 211, and 311, respectively.

The upper transistors 12, 22, and 32 formed on the lower transistors 11, 21, and 31 may include one or more upper channel layers 121, 221, and 321, respectively, and upper gate structures 122, 222, and 322 enclosing the one or more upper channel layers 121, 221, and 321, respectively.

The lower source/drain structure described above may be formed at both ends of the lower channel layers 111, 211, and 311 in the second direction, the lower source/drain structures may be connected through the lower channel layers 111, 211, and 311 serving as current flow channels of the lower transistors 11, 21, and 31, respectively.

The upper source/drain structure described above may be formed at both ends of the upper channel layers 121, 221, and 321 in the second direction, and the upper source/drain structures may be connected through the upper channel layers 121, 221, and 321 serving as current flow channels of the upper transistors 12, 22, and 32, respectively.

The lower channel layers 111, 211, and 311 or the upper channel layers 121, 221, and 321 may be nanosheet films arranged in the third direction and including a semiconductor material. For example, the nanosheet films may include silicon (Si) or silicon-germanium (SiGe). The nanosheets may be obtained through multiple processes including photolithography and subtractive etch, but are not limited thereto.

The source/drain structure may be obtained by epitaxial growth of the substrate A, and/or the lower channel layers 111, 211, and 311, and/or the upper channel layers 121, 221, and 321. The source/drain structure may also include a material forming the substrate A and/or the lower channel layers 111, 211, and 311, and/or the upper channel layers 121, 221, and 321.

Each of the lower gate structures 112, 212, and 312 and the upper gate structures 122, 222, and 322 may be formed of a plurality of films including a work function metal film and a gate electrode film. The work function metal film may include titanium (Ti), tantalum (Ta), or a compound thereof, and the gate electrode film may include copper (Cu), aluminum (Al), tungsten (W), molybdenum (Mo), ruthenium (Ru) or compounds thereof. However, the example is not limited thereto.

The lower gate structures 112, 212, and 312 and the upper gate structures 122, 222, and 322 may be formed through a process, such as atomic layer deposition (ALD), CVD, physical vapor deposition (PVD), PECVD, RIE, chemical oxide removal (COR), or a combination thereof.

A top surface, a bottom surface, and a side surface of each of the channel layers 111 and 121 may be covered with a gate insulating layer GIL based on the first direction D1 and the third direction D3. The gate insulating layer GIL may be formed between each of the channel layers 111 and 121 and each of the respective gate structures 112 and 122. For example, the gate insulating layer GIL may contact the channel layers 111 and 121 and the gate structures 112 and 122. The gate insulating layer GIL may not be formed on a surface on which each of the channel layers 111 and 121 is in contact with the source/drain structures described above.

The gate insulating layer GIL may include an interfacial layer formed of silicon oxide or silicon oxynitride, but the example is not limited thereto. The gate insulating layer GIL may include a high-k dielectric layer formed of hafnium oxide, hafnium silicate, hafnium oxynitride, hafnium silicon oxynitride, and hafnium. The gate insulating layer GIL may also include a high-k dielectric layer formed of aluminum oxide, lanthanum oxide, lanthanum aluminum oxide, zirconium oxide, zirconium silicate, zirconium oxynitride, silicon zirconium oxide, titanium oxide, barium strontium titanium oxide, barium titanium oxide, strontium titanium oxide, yttrium oxide, tantalum oxide, or lead scandium tantalum oxide, but the example is not limited thereto.

The intermediate insulating layers 13, 23, and 33 may be disposed between the lower gate structures 112, 212, and 312 and the upper gate structures 122, 222, and 322, respectively. The intermediate insulating layers 13, 23, and 33 may contact upper surfaces of the lower gate structures 112, 212, and 312 and lower surfaces of the upper gate structures 122, 222, and 322.

The first lower gate structure 112, the first intermediate insulating layer 13, and the first upper gate structure 122 that form the first transistor stack 10 may be surrounded by the interlayer dielectric B. For example, the interlayer dielectric B may contact the first lower gate structure 112, the first intermediate insulating layer 13, and the first upper gate structure 122.

The second lower gate structure 212, the second intermediate insulating layer 23, and the second upper gate structure 222 that form the second transistor stack 20 may be surrounded by the interlayer dielectric B. For example, the interlayer dielectric B may contact the second lower gate structure 212, the second intermediate insulating layer 23, and the second upper gate structure 222.

The third lower gate structure 312, the third intermediate insulating layer 33, and the third upper gate structure 322 that form the third transistor stack 30 may be surrounded by the interlayer dielectric B. For example, the interlayer dielectric B may contact the third lower gate structure 312, the third intermediate insulating layer 33, and the third upper gate structure 322.

A sum of the numbers of the first lower channel layers 111 and the first upper channel layers 121 of the first transistor stack 10 may be different from a sum of the numbers of the second lower channel layers 211 and the second upper channel layers 221 of the second transistor stack 20.

A sum of the numbers of the first lower channel layers 111 and the first upper channel layers 121 of the first transistor stack 10 may be different from a sum of the numbers of the third lower channel layers 311 and the third upper channel layers 321 of the third transistor stack 30.

The number of first lower channel layers 111 may be the same as the number of second lower channel layers 211, whereas the number of first upper channel layers 121 may be different from the number of second upper channel layers 221. However, the example is not limited thereto, and the number of first upper channel layers 121 may be the same as the number of second upper channel layers, whereas the number of first lower channel layers 111 may be different from the number of second lower channel layers.

The number of first lower channel layers 111 may be the same as the number of third lower channel layers 311, whereas the number of first upper channel layers 121 may be different from the number of third upper channel layers 321. However, the example is not limited thereto, and the number of first upper channel layers 121 may be different from the number of third upper channel layers, whereas the number of first lower channel layers 111 may be the same as the number of third lower channel layers.

The sum of the numbers of the first lower channel layers 111 and the first upper channel layers 121 of the first transistor stack 10 may be greater than the sum of the numbers of the second lower channel layers 211 and the second upper channel layers 221 of the second transistor stack 20.

The sum of the numbers of the third lower channel layers 311 and the third upper channel layers 321 of the third transistor stack 30 may be the same as the sum of the numbers of the second lower channel layers 211 and the second upper channel layers 221 of the second transistor stack 20.

The number of third upper channel layers 321 may be different from the number of second upper channel layers 221, and the number of third lower channel layers 311 may be different from the number of second lower channel layers 211.

The number of first upper channel layers 121 of the first transistor stack 10 may be two, and the number of first lower channel layers 111 may be two. The second upper channel layers 221 of the second transistor stack 20 may be one, and the number of second lower channel layers 211 may be two. The third upper channel layers 321 of the third transistor stack 30 may be two and the number of third lower channel layers 311 may be one.

A width L1 of the first upper channel layer 121 and the first lower channel layer 111 of the first transistor stack 10, a width L2 of the second upper channel layer 221 and the second lower channel layer 211 of the second transistor stack 20, or a width L3 of the third upper channel layer 321 and the third lower channel layer 311 of the third transistor stack 30 may be different from or the same as each other. The width of channel layer may be a distance extending in the first direction D1.

Referring to FIG. 3A, a slit described below may not be separately formed in the first transistor stack 10. The first lower gate contact 113 may extend by penetrating the substrate A. The first lower gate contact 113 may be connected to the first lower gate structure 112. For example, the first lower gate contact 113 may contact the first lower gate structure 112. The first upper gate contact 123 may extend by penetrating the interlayer dielectric B. The first upper gate contact 123 may be connected to the first upper gate structure 122. For example, the first upper gate contact 123 may contact the first upper gate structure 122.

Referring to FIG. 3B, the second upper transistor 22 of the second transistor stack 20 may include a first slit 224. The first slit 224 may remove a portion of the second upper gate structure 222. Through the feature of the first slit 224, a portion of the second upper channel layer 221 disposed in the second upper gate structure 222 may be removed together with the portion of the second upper gate structure 222.

One of the second upper channel layers 221 disposed in the second upper gate structure 222 may be removed by the first slit 224, and only one second upper channel layer 221 may remain in the second upper gate structure 222.

Accordingly, the number of second upper channel layers 221 disposed in the second upper transistor 22 of the second transistor stack 20 may be formed differently from the number of first upper channel layers 121 disposed in the first upper transistor 12 of the first transistor stack 10 shown in FIG. 3A. In addition, the number of second upper channel layers 221 disposed in the second upper transistor 22 of the second transistor stack 20 may be formed differently from the number of third upper channel layers 321 disposed in the third upper transistor 32 of the third transistor stack 30 shown in FIG. 3C.

The inside of the first slit 224 may be filled with an insulating material E. The insulating material E may contact the second upper gate structure 222. A lower surface of the insulating material E may be at a lower vertical level than an upper surface of the second upper gate structure 222. The insulating material E may be formed of the same material as the interlayer dielectric B. The insulating material E may be formed of silicon oxide (SiO), silicon nitride (SiN), and/or silicon oxynitride (SiON). However, the example is not limited thereto.

The insulating material E may be formed of a different material from the interlayer dielectric B. In the same way, the insulating material E formed on an area from which some channels of the upper channel layer are removed, may be referred to as an upper channel layer cut.

The second lower gate contact 213 may extend by penetrating the substrate A. The second lower gate contact 213 may be connected to the second lower gate structure 212. For example, the second lower gate contact 213 may contact the second lower gate structure 212. The second upper gate contact 223 may extend by penetrating the insulating material E filling the inside of the first slit 224. For example, lower surfaces of the second upper gate contact 223 and the insulating material E may be coplanar. The second upper gate contact 223 may be connected to the second upper gate structure 222. The second upper gate contact 223 may contact the second upper gate structure 222.

A width of the insulating material E filling a portion removed by the first slit in the second upper gate structure 222 in the first direction D1 may be less than or equal to a width of the second upper gate structure 222 in the first direction D1. A width of a bottom surface of the insulating material E filling the removed portion in the second upper gate structure 222 in the first direction D1 may be equal to or greater than a width of the second upper channel layer 221 in the first direction D1. In example embodiments, the width of the bottom surface of the insulating material E may be less than a width of an upper surface of the insulating material E.

A width of the second upper gate contact 223 in the first direction D1 may be less than the width of the insulating material E filling the removed portion in the second upper gate structure 222 in the first direction D1. A width of a bottom surface of the second upper gate contact 223 in contact with the second upper gate structure 222 in the first direction D1 may be less than the width of the second upper gate structure 222 in the first direction D1. In example embodiments, a width of the second upper gate contact 223 may be uniform along its length in the third direction D3.

Referring to FIG. 3C, the third lower transistor 31 of the third transistor stack 30 may include a second slit 314. The second slit 314 may remove a portion of the third lower gate structure 312. Through the feature of the second slit 314, a portion of the third lower channel layer 311 disposed in the third lower gate structure 312 may be removed together with the portion of the third lower gate structure 312.

One of the third lower channel layers 311 disposed in the third lower gate structure 312 may be removed by the second slit 314, and only one third lower channel layer 311 may remain in the third lower gate structure 312.

Accordingly, the number of third lower channel layers 311 disposed in the third lower transistor 31 of the third transistor stack 30 may be formed differently from the number of first lower channel layers 111 disposed in the first lower transistor 11 of the first transistor stack 10 shown in FIG. 3A. In addition, the number of third lower channel layers 311 disposed in the third lower transistor 31 of the third transistor stack 30 may be formed differently from the number of second lower channel layers 211 disposed in the second lower transistor 21 of the second transistor stack 20.

The inside of the second slit 314 may be filled with the insulating material E. The insulating material E may contact the third lower gate structure 312. An upper surface of the insulating material E may be at a higher vertical level than a lower surface of the third lower gate structure 312. The insulating material E may be formed of the same material as the interlayer dielectric B. The insulating material E may be formed of silicon oxide (SiO), silicon nitride (SiN), and/or silicon oxynitride (SiON). However, the example is not limited thereto.

The insulating material E may be formed of a different material from the interlayer dielectric B. In the same way, the insulating material E formed on an area from which some channels of the lower channel layer are removed may be referred to as a lower channel layer cut.

The third lower gate contact 313 may extend by penetrating the insulating material E filling the inside of the second list 314. The third lower gate contact 313 may be connected to the third lower gate structure 312. For example, the third lower gate contact 313 may contact the third lower gate structure 312. The third upper gate contact 323 may extend by penetrating the insulating material E. For example, an upper surface of the third upper gate contact 323 may be coplanar with an upper surface of the insulating material E. The third upper gate contact 323 may be connected to the third upper gate structure 322. For example, the third upper gate contact 323 may contact the third upper gate structure 322.

A width of the insulating material E filling a portion removed by the second slit in the third lower gate structure 312 in the first direction D1 may be less than or equal to a width of the third lower gate structure 312 in the first direction D1. A width of a top surface of the insulating material E filling the removed portion in the third lower gate structure 312 in the first direction D1 may be equal to or greater than a width of the third lower channel layer 311 in the first direction D1.

A width of the third lower gate contact 313 in the first direction D1 may be less than the width of the insulating material E filling the removed portion in the third lower gate structure 312 in the first direction D1. A width of a top surface of the third lower gate contact 313 in contact with the third lower gate structure 312 in the first direction D1 may be less than the width of the third lower gate structure 312 in the first direction D1. In example embodiments, a width of the third lower gate structure 312 may be uniform along its length in the third direction D3.

Hereinafter, a repeated description of the technical ideas described above that may be identically applicable is not repeated and differences in the semiconductor device according to various other embodiments are described.

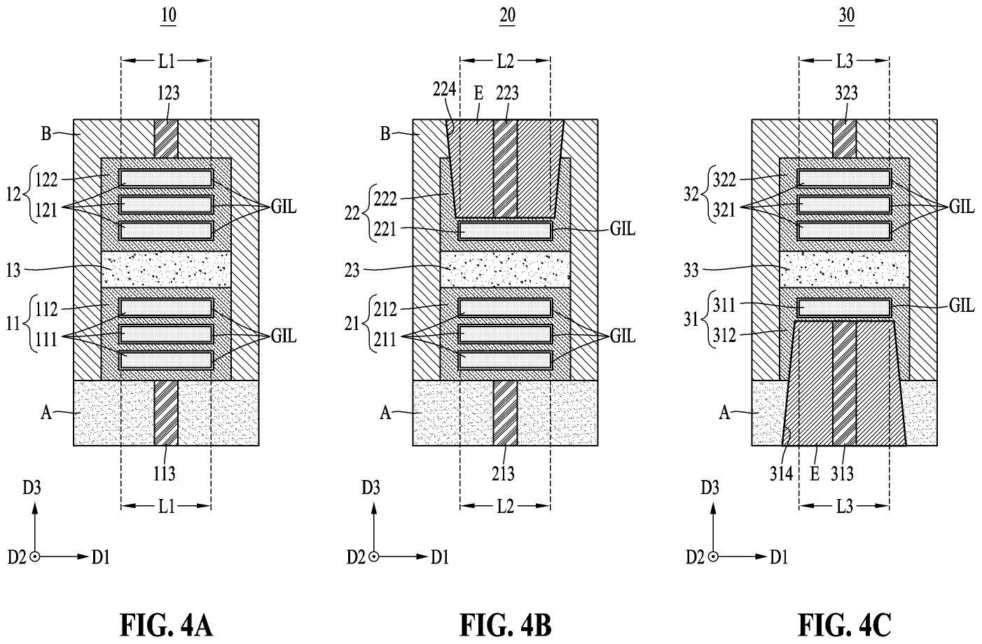

FIG. 4A is a cross-sectional view taken along line I-I′ of FIG. 1 and is a cross-sectional view of a first transistor stack of a semiconductor device according to another example embodiment. FIG. 4B is a cross-sectional view taken along line J-J′ of FIG. 1 and is a cross-sectional view of a second transistor stack of a semiconductor device according to another example embodiment. FIG. 4C is a cross-sectional view taken along line K-K′ of FIG. 1 and is a cross-sectional view of a third transistor stack of a semiconductor device according to another example embodiment.

Referring to FIGS. 4A to 4C, the number of first upper channel layers 121 of the first transistor stack 10 may be three and the number of first lower channel layers 111 may be three. The number of second upper channel layers of the second transistor stack 20 may be one and the number of second lower channel layers 211 may be three. The number of third upper channel layers 321 of the third transistor stack 30 may be three and the number of third lower channel layers 311 may be one.

A width L1 of the first upper channel layer 121 and the first lower channel layer 111 of the first transistor stack 10, a width L2 of the second upper channel layer 221 and the second lower channel layer 211 of the second transistor stack 20, or a width L3 of the third upper channel layer 321 and the third lower channel layer 311 of the third transistor stack 30 may be different from or the same as each other. A width of the channel layer may be a length extending in the first direction D1.

Two second upper channel layers 221 disposed in the second upper gate structure 222 of the second transistor stack 20 may be removed by the first slit 224, and only one second upper channel layer 221 may remain in the second upper gate structure 222.

Two third lower channel layers 311 disposed in the third lower gate structure 312 of the third transistor stack 30 may be removed by the second slit 314 and only one third lower gate structure 312 may remain in the third lower channel layer 311.

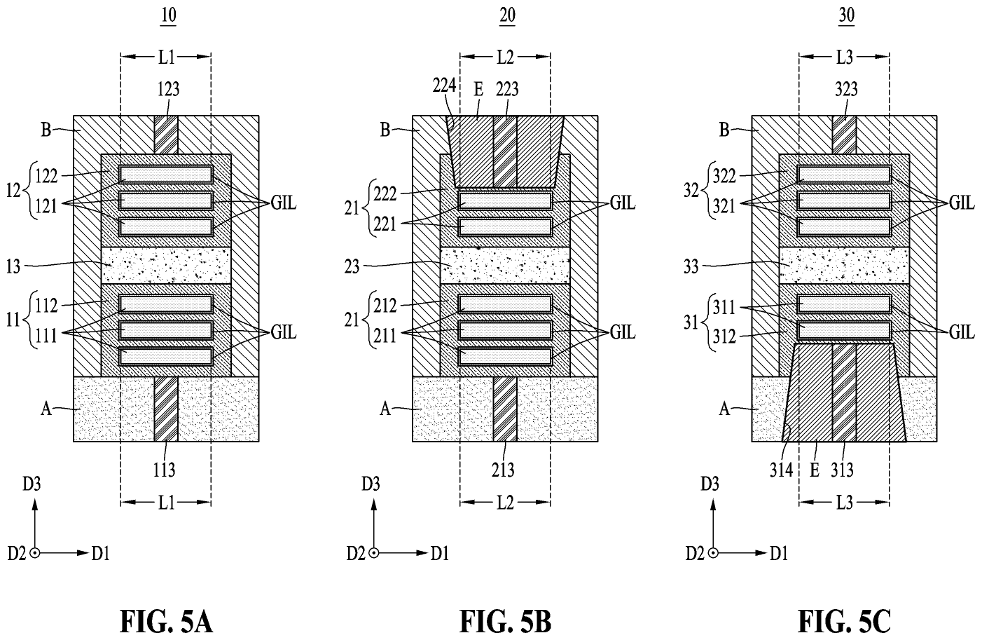

FIG. 5A is a cross-sectional view taken along line I-I′ of FIG. 1 and is a cross-sectional view of a first transistor stack of a semiconductor device according to another example embodiment. FIG. 5B is a cross-sectional view taken along line J-J′ of FIG. 1 and is a cross-sectional view of a second transistor stack of a semiconductor device according to another example embodiment. FIG. 5C is a cross-sectional view taken along line K-K′ of FIG. 1 and is a cross-sectional view of a third transistor stack of a semiconductor device according to another example embodiment.

Referring to FIGS. 5A to 5C, the number of first upper channel layers 121 of the first transistor stack 10 may be three and the number of first lower channel layers 111 may be three. The number of second upper channel layers 221 of the second transistor stack 20 may be two and the number of second lower channel layers 211 may be three. The number of third upper channel layers 321 of the third transistor stack 30 may be three and the number of third lower channel layers 311 may be two.

A width L1 of the first upper channel layer 121 and the first lower channel layer 111 of the first transistor stack 10, a width L2 of the second upper channel layer 221 and the second lower channel layer 211 of the second transistor stack 20, or a width L3 of the third upper channel layer 321 and the third lower channel layer 311 of the third transistor stack 30 may be different from or the same as each other. A width of the channel layer may be a length extending in the first direction D1.

One second upper channel layer 221 disposed in the second upper gate structure 222 of the second transistor stack 20 may be removed by the first slit 224 and two second upper channel layers 221 may remain in the second upper gate structure 222.

One third lower channel layer 311 disposed in the third lower gate structure 312 of the third transistor stack 30 may be removed by the second slit 314 and two third lower gate structures 312 may remain in the third lower channel layer 311.

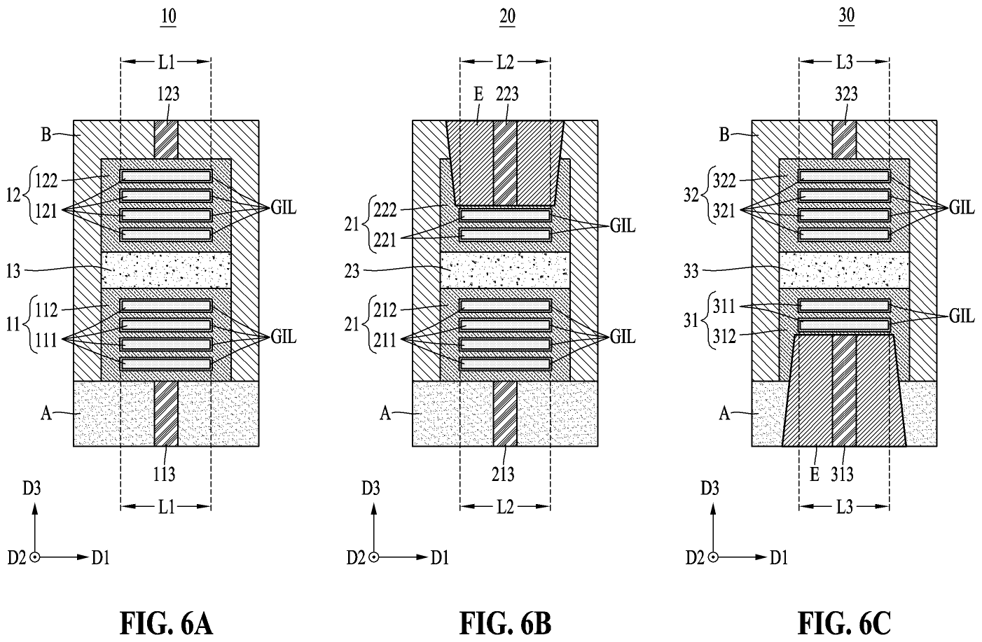

FIG. 6A is a cross-sectional view taken along line I-I′ of FIG. 1 and is a cross-sectional view of a first transistor stack of a semiconductor device according to another example embodiment. FIG. 6B is a cross-sectional view taken along line J-J′ of FIG. 1 and is a cross-sectional view of a second transistor stack of a semiconductor device according to another example embodiment. FIG. 6C is a cross-sectional view taken along line K-K′ of FIG. 1 and is a cross-sectional view of a third transistor stack of a semiconductor device according to another example embodiment.

Referring to FIGS. 6A to 6C, the number of first upper channel layers 121 of the first transistor stack 10 may be four and the number of first lower channel layers 111 may be four. The number of second upper channel layers 221 of the second transistor stack 20 may be two and the number of second lower channel layers 211 may be four. The number of third upper channel layers 321 of the third transistor stack 30 may be four and the number of third lower channel layers 311 may be two.

A width L1 of the first upper channel layer 121 and the first lower channel layer 111 of the first transistor stack 10, a width L2 of the second upper channel layer 221 and the second lower channel layer 211 of the second transistor stack 20, or a width L3 of the third upper channel layer 321 and the third lower channel layer 311 of the third transistor stack 30 may be different from or the same as each other. A width of the channel layer may be a length extending in the first direction D1.

Two second upper channel layers 221 disposed in the second upper gate structure 222 of the second transistor stack 20 may be removed by the first slit 224 and two second upper channel layers 221 may remain in the second upper gate structure 222.

Two third lower channel layers 311 disposed in the third lower gate structure 312 of the third transistor stack 30 may be removed by the second slit 314 and two third lower gate structures 312 may remain in the third lower channel layer 311.

However, the numbers of channel layers of the first transistor stack 10, the second transistor stack 20, and the third transistor stack 30 are not limited thereto, and may be formed as various combinations of numbers.

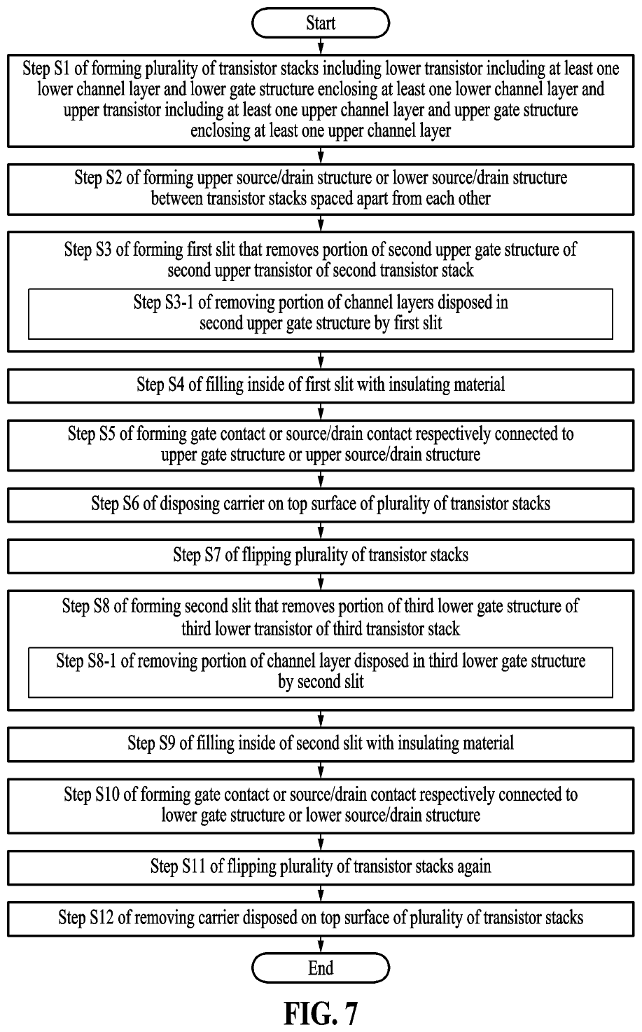

FIG. 7 is a flowchart of a method of manufacturing a semiconductor device according to an example embodiment of the present disclosure.

Referring to FIG. 7, a method of manufacturing a semiconductor device according to various embodiments may include step S1 of forming a plurality of transistor stacks including a lower transistor including at least one lower channel layer and a lower gate structure enclosing the at least one lower channel layer and an upper transistor including an upper gate structure including at least one upper channel layer and an upper gate structure enclosing the at least one upper channel layer, step S2 of forming an upper source/drain structure or a lower source/drain structure between transistor stacks spaced apart from each other, step S3 of forming a first slit that removes a portion of a second upper gate structure of a second upper transistor of a second transistor stack, step S4 of filling an inside of the first slit with an insulating material, and step S5 of forming a gate contact or a source/drain contact connected to an upper gate structure or the upper source/drain structure, respectively.

The method of manufacturing the semiconductor device may further include step S6 of disposing a carrier on a top surface of the plurality of transistor stacks, step S7 of flipping the plurality of transistor stacks, step S8 of forming a second slit that removes a portion of a third lower gate structure of a third lower transistor of a third transistor stack, step S9 of filling an inside of the second slit with an insulating material, and step S10 of forming a gate contact or a source/drain contact connected to a lower gate structure or the lower source/drain structure, respectively.

The method of manufacturing the semiconductor device may further include step S11 of flipping the plurality of transistor stacks again and step S12 of removing the carrier disposed on the top surface of the plurality of transistor stacks.

Step S3 of forming the first slit may include step S3-1 of removing a portion of a channel layer disposed in the second upper gate structure by the first slit.

Step S8 of forming the second slit may include step S8-1 of removing a portion of a channel layer disposed in the third lower gate structure by the second slit.

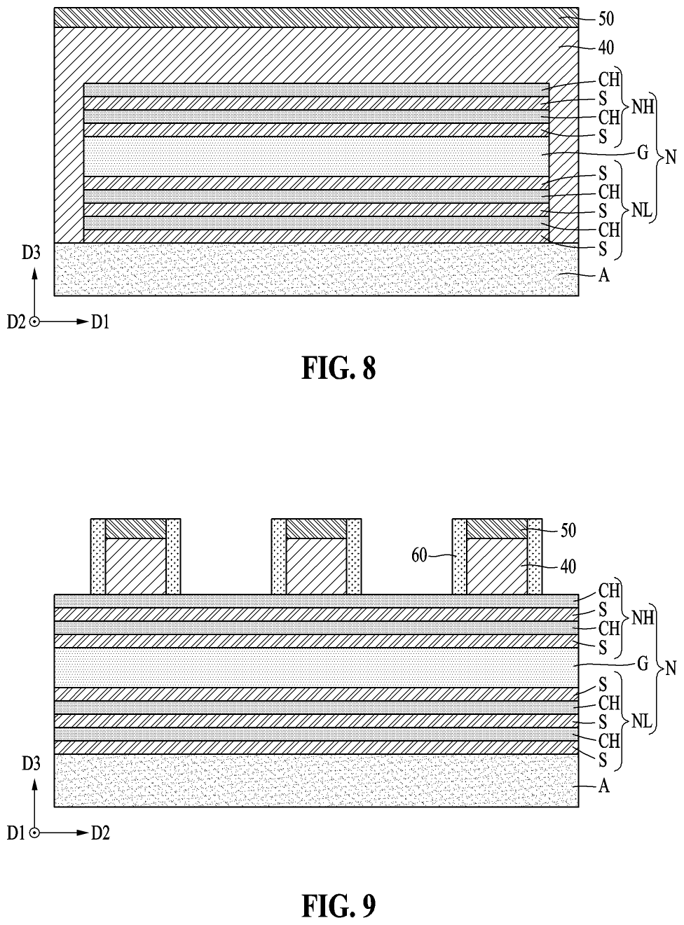

FIGS. 8 to 27 illustrate a manufacturing process of a semiconductor device according to an example embodiment of the present disclosure.

Referring to FIGS. 8 and 9, a dummy gate structure 40 may enclose a multi-stack nanosheet structure N. The multi-stack nanosheet structure N may be formed of a lower nanosheet stack NL, a separation structure G, and an upper nanosheet stack NH. The lower nanosheet stack NL may be disposed on the substrate A. The separation structure G may be disposed on the lower nanosheet stack NL. The upper nanosheet stack NH may be disposed on the separation structure G. The lower nanosheet stack NL or the upper nanosheet stack NH may be formed of a plurality of sacrificial layers S and a plurality of channel layers CH. A hard mask pattern 50 may be formed on an upper surface of the dummy gate structure 40, and a gate spacer 60 may be formed on a side surface of the dummy gate structure 40.

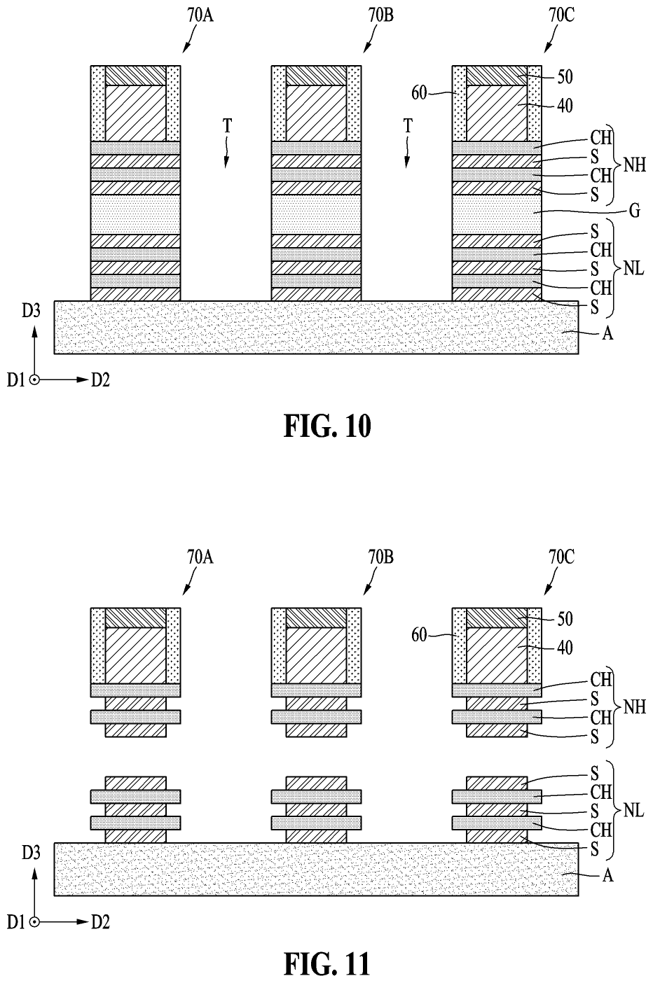

Referring to FIG. 10, the multi-stack nanosheet structure N of FIG. 9 may be divided into a plurality of multi-stack nanosheet structures 70A to 70C on the substrate A. The plurality of multi-stack nanosheet structures 70A to 70C may be obtained by etching the exposed multi-stack nanosheet structure N between the dummy gate structures 40. Trenches T that expose the upper surface of the substrate A upward may be obtained by an etching process.

Referring to FIG. 11, the separation structure G may be removed to form an intermediate insulating layer. A portion of the sacrificial layers S disposed on the lower side of the gate spacer 60 may be removed to form an internal spacer.

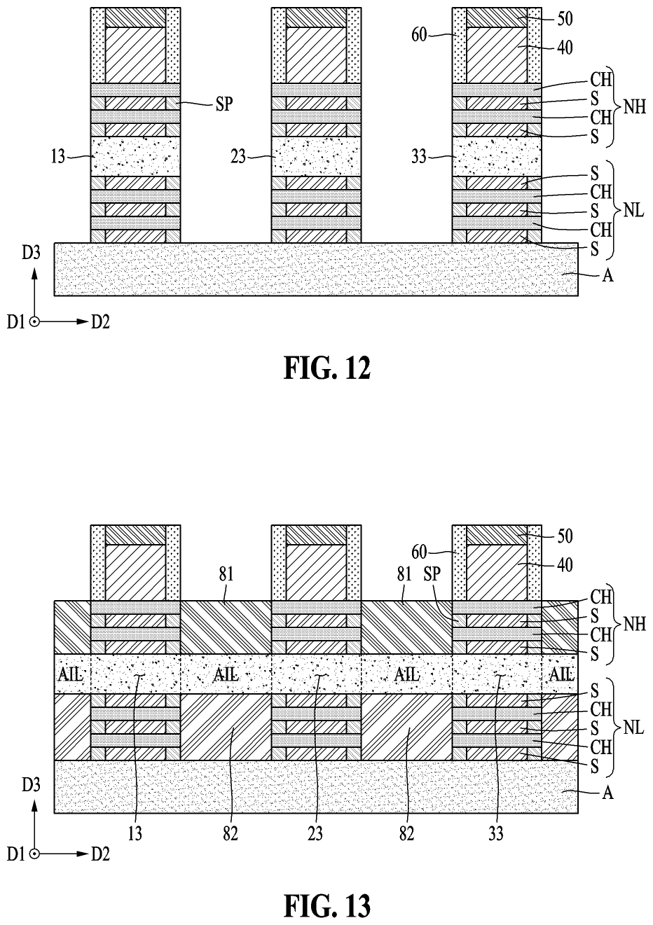

Referring to FIG. 12, the intermediate insulating layers 13, 23, and 33 may be formed in a space from which the separation structure G is removed. Internal spacers SP may be formed in the space from which the portion of the sacrificial layers S is removed. The internal spacers SP may be formed by, for example, ALD, plasma enhanced ALD (PEALD), CVD, PECVD, or a combination thereof. However, the example is not limited thereto.

The internal spacers SP may not be formed in the space from which the portion of the sacrificial layers S is removed. In this case, the space from which the portion of the sacrificial layers S is removed may be filled through a process of forming a gate structure described below.

A gate insulating layer may be disposed between a channel layer and a gate structure. The gate structure and the gate insulating layer are further described in a subsequent process step. Referring to FIG. 13, source/drain structures 81 and 82 may be formed at both ends of the lower nanosheet stack NL or the upper nanosheet stack NH, respectively. Additional intermediate insulating layers AIL connecting adjacent intermediate insulating layers may be formed between the intermediate insulating layers 13, 23, and 33. The additional intermediate insulating layers AIL may be formed of a material that is the same as or similar to the intermediate insulating layer. However, the example is not limited thereto.

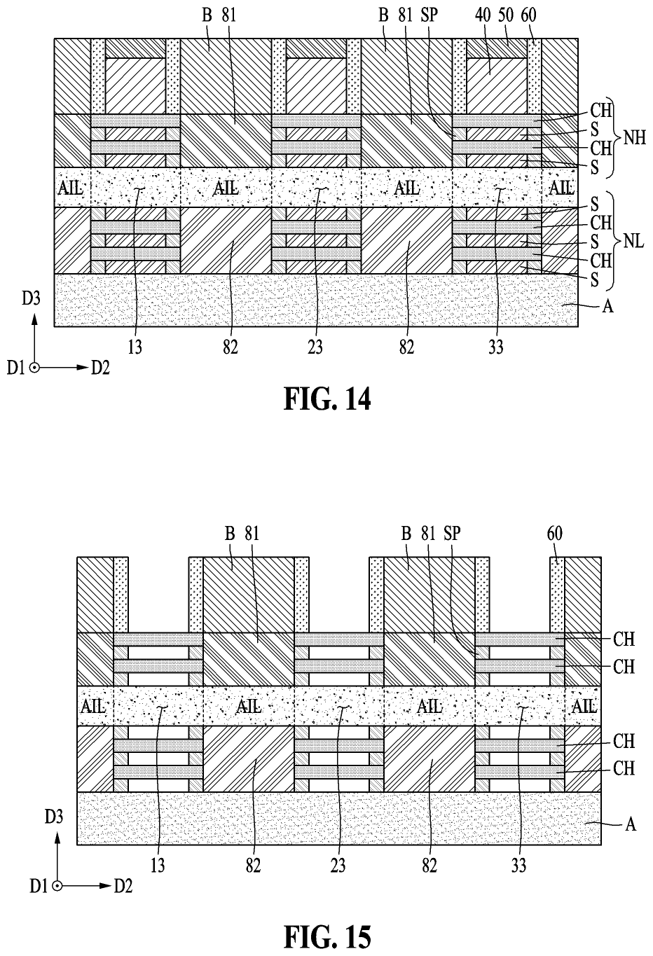

Referring to FIG. 14, the interlayer dielectric B may be deposited on an area in which the source/drain structures 81 and 82 are formed. The source/drain structures 81 and 82 may be separated from each other or other circuit elements by the interlayer dielectric B.

Referring to FIG. 15, the hard mask pattern 50, the dummy gate structure 40, and the sacrificial layers S that are disposed on an upper part may be removed.

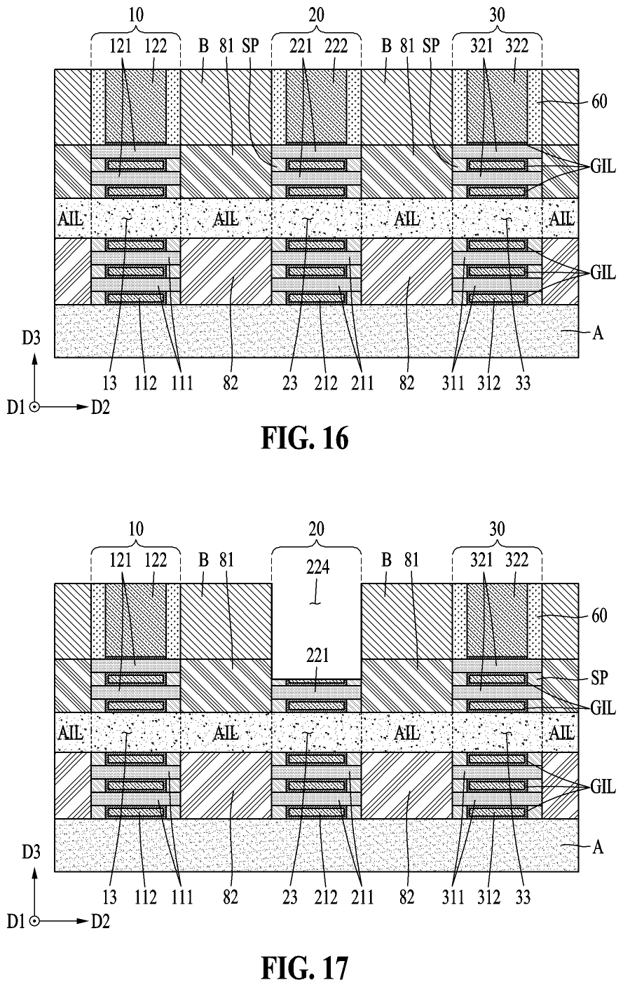

Referring to FIG. 16, a gate structure may be formed on channel layers. A space from which the dummy gate structure and the sacrificial layers are removed may be filled with the lower gate structures 112, 212, and 312 and the upper gate structures 122, 222, and 322. As a result, the plurality of transistor stacks 10, 20, and 30 may be formed on the substrate A.

A channel layer disposed inside the first lower gate structure 112 of the first transistor stack 10 may be defined as the first lower channel layer 111. A channel layer disposed inside the first upper gate structure 122 of the first transistor stack 10 may be defined as the first upper channel layer 121.

A channel layer disposed inside the second lower gate structure 211 of the second transistor stack 20 may be defined as the second lower channel layer 211. A channel layer disposed inside the second upper gate structure 222 of the second transistor stack 20 may be defined as the second upper channel layer 221.

A channel layer disposed inside the third lower gate structure 312 of the third transistor stack 30 may be defined as the third lower channel layer 311. A channel layer disposed inside the third upper gate structure 322 of the third transistor stack 30 may be defined as the third upper channel layer 321.

The gate insulating layer GIL that encloses each of the channel layers 111, 121, 211, 221, 311, 321 may be formed. The gate insulating layer GIL may be formed between each of the channel layers 111, 121, 211, 221, 311, and 321 and each of the gate structures 112, 122, 212, 222, 312, and 322. Except for a surface in which each of the channel layers 111, 121, 211, 221, 311, and 321 is in contact with the source/drain structures 81 and 82, a top surface, a bottom surface, and a side surface of each of the channel layers 111, 121, 211, 221, 311, and 321 may be covered with the gate insulating layer GIL. For example, the gate insulating layer GIL may contact the top surface, the bottom surface, and the side surface of each of the channel layers 111, 121, 211, 221, 311, and 321.

Referring to FIG. 17, the first slit 224 that removes a portion of the second upper gate structure 222 of the second structure 20 may be formed by an etching process. One second upper channel layer disposed in the second upper gate structure 222 may be removed by the first slit 224. The gate spacers 60 disposed on both sides of the second upper gate structure 222 may also be removed by the first slit 224. As a result, the number of second upper channel layers 221 of the second transistor stack 20 may be one and the number of second lower channel layers 211 may be two.

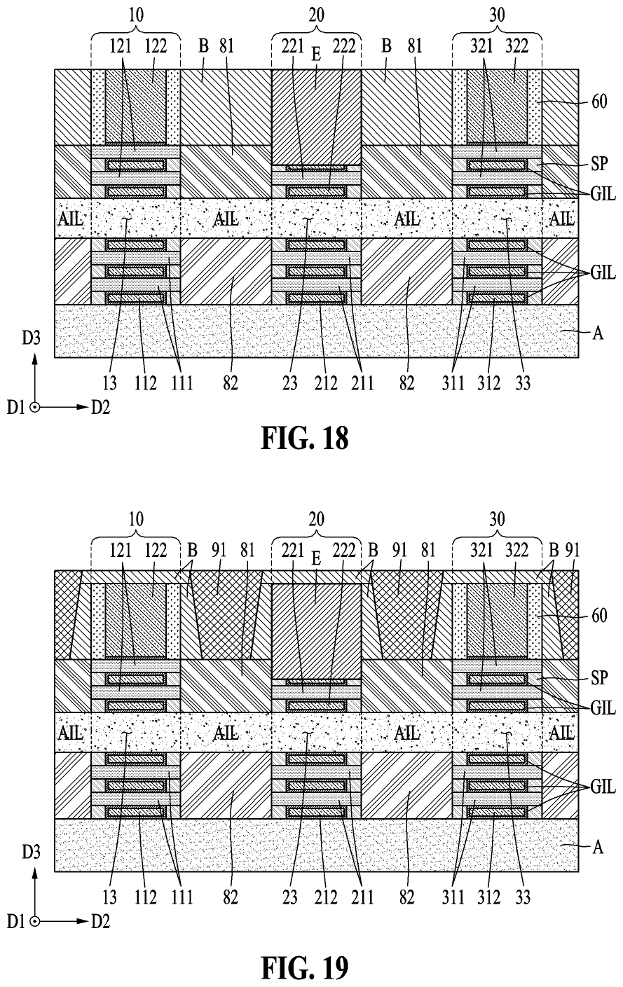

Referring to FIG. 18, the portion removed by the first slit may be filled with the insulating material E. The insulating material E may be formed of the same material as the interlayer dielectric B. The insulating material E may be formed of silicon oxide (SiO), silicon nitride (SiN), and/or silicon oxynitride (SiON). However, the example is not limited thereto. The insulating material E may be formed of a different material from the interlayer dielectric B.

Referring to FIG. 19, the interlayer dielectric B may be additionally deposited on the plurality of transistor stacks 10, 20, and 30. Each of the transistor stacks 10, 20, and 30 may be separated from each other or other circuit elements by the interlayer dielectric B. Upper source/drain structures 91 respectively connected to the upper source/drain structures 81 disposed between the plurality of transistor stacks may be formed.

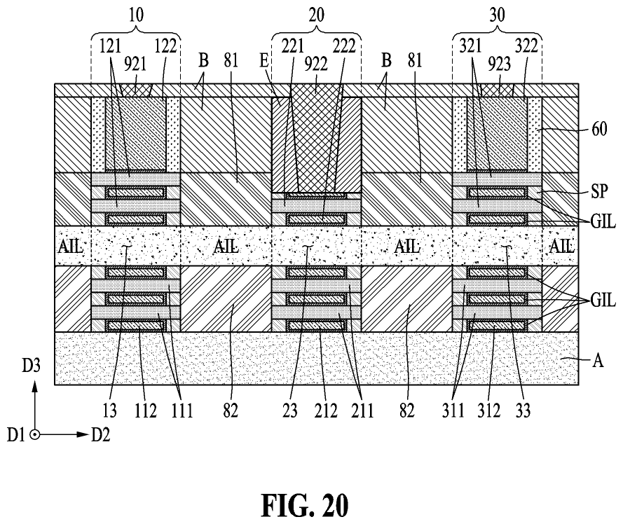

FIG. 20 illustrates a cross-sectional view viewing in the same direction from a position apart in the first direction D1 based on FIG. 19. Referring to FIG. 20, upper gate contacts 921, 922, and 923 respectively connected to the upper gate structures 122, 222, and 322 of the plurality of transistor stacks may be formed. The first upper gate contact 921 and the third upper gate contact 923 respectively connected to the first upper gate structure 122 and the third upper gate structure 322 may extend by penetrating the interlayer dielectric B. The second upper gate contact 922 connected to the second upper gate structure 222 may extend by penetrating the interlayer dielectric B and the insulating material E.

However, the order of forming the upper source/drain contact 91 and the upper gate contacts 921, 922, and 923 may be interchanged. In addition, on the upper source/drain contact 91 and the upper gate contacts 921, 922, and 923, an upper wiring layer connected thereto may be formed.

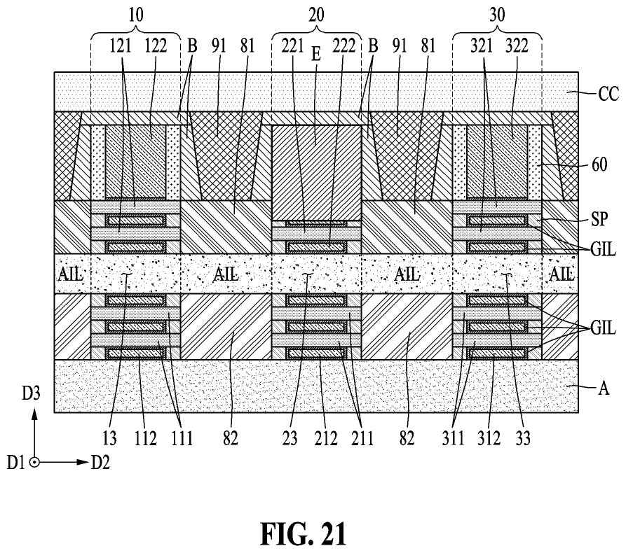

Referring to FIG. 21, a carrier CC may be disposed on the top surface of the plurality of transistor stacks. Other structures, such as the upper wiring layer, may be further included between the carrier CC and the upper source/drain contact 91, between the carrier CC and the upper gate contacts 921, 922, 923, and between the carrier CC and the interlayer dielectric B, but are not repeated for ease of description.

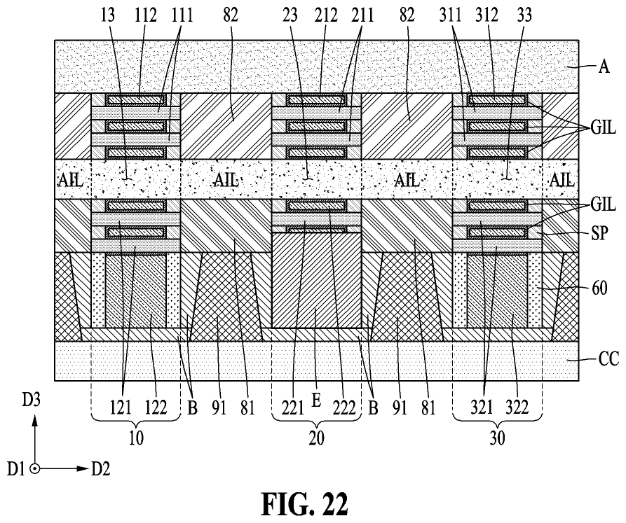

Referring to FIG. 22, a semiconductor device in which the plurality of transistor stacks is formed may be flipped using the carrier CC such that the substrate A faces upward.

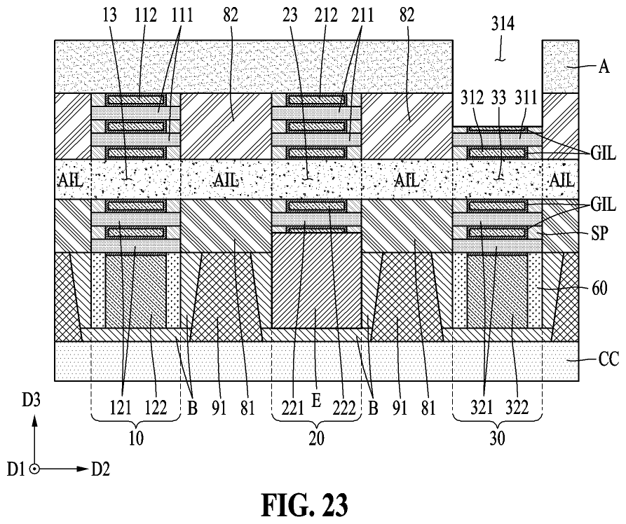

Referring to FIG. 23, the second slit 314 that removes a portion of the third lower gate structure 312 of the third transistor stack 30 and the substrate A may be formed by an etching process. One third lower channel layer disposed in the third lower gate structure 312 may be removed by the second slit 314. As a result, the number of third lower channel layers 311 of the third transistor stack 30 may be one and the number of third upper channel layers 321 may be two.

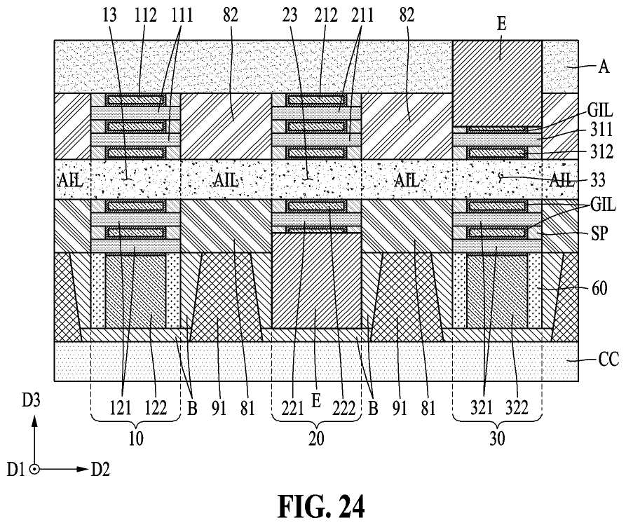

Referring to FIG. 24, the portion removed by the second slit may be filled with the insulating material E. The insulating material E may be formed of the same material as the interlayer dielectric B. The insulating material E may be formed of silicon oxide (SiO), silicon nitride (SiN), and/or silicon oxynitride (SiON). However, the example is not limited thereto. The insulating material E may be formed of a different material from the interlayer dielectric B.

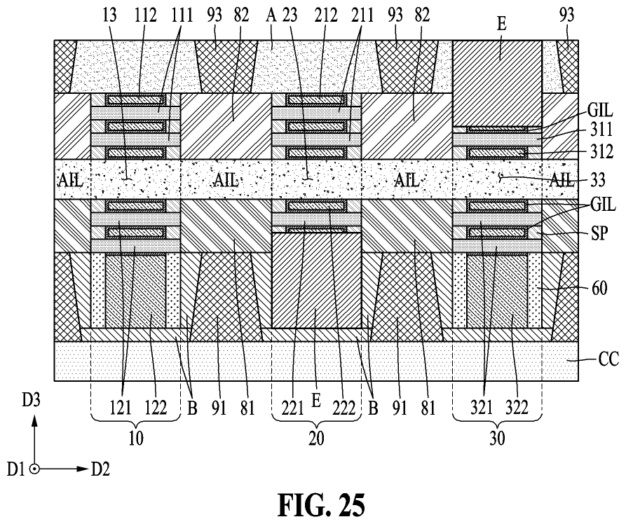

Referring to FIG. 25, lower source/drain structures 93 respectively connected to the lower source/drain structures 82 disposed between the plurality of transistor stacks may be formed.

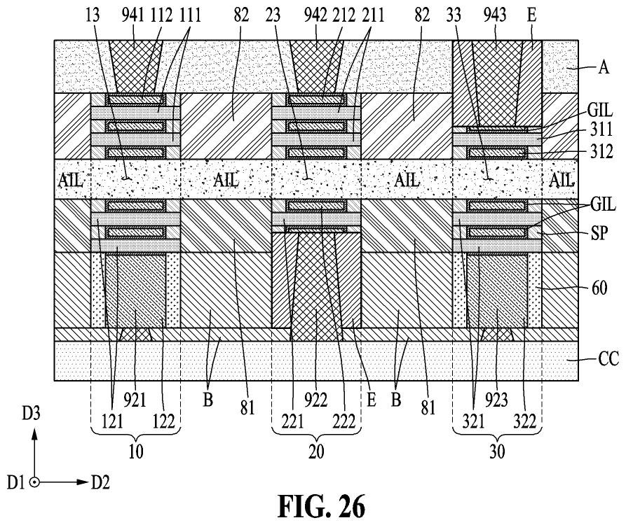

FIG. 26 illustrates a cross-sectional view viewing in the same direction from a position apart in the first direction D1 based on FIG. 25. Referring to FIG. 26, lower gate contacts 941, 942, and 943 respectively connected to the lower gate structures 112, 212, and 312 of the plurality of transistor stacks may be formed. The first lower gate contact 941 and the second lower gate contact 942 respectively connected to the first lower gate structure 112 and the second lower gate structure 212 may extend by penetrating the substrate A. The third lower gate contact 943 connected to the third lower gate structure 312 may extend by penetrating the substrate A and the insulating material E.

However, the order of forming the lower source/drain contact 93 and the lower gate contacts 941, 942, and 943 may be interchanged. In addition, on the lower source/drain contact 93 and the lower gate contacts 941, 942, and 943, a lower wiring layer connected thereto may be formed.

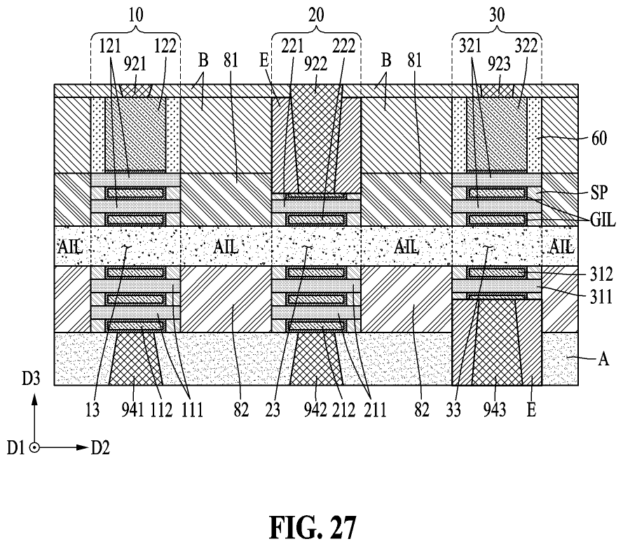

Referring to FIG. 27, after the semiconductor device in which the plurality of transistor stacks is formed is flipped again using the carrier such that the substrate A faces downward, the carrier may be removed. The semiconductor device manufactured through the process described above may include a plurality of transistor stacks having different combinations of the number of channel layers.

In other words, the number of first upper channel layer 121 of the first transistor stack 20 may be two and the number of first lower channel layers 111 may be two. The second upper channel layers 221 of the second transistor stack 20 may be one, and the number of second lower channel layers 211 may be two. The third upper channel layers 321 of the third transistor stack 30 may be two and the number of third lower channel layers 311 may be one.

A width of the insulating material E filling the portion removed by the first slit in the second upper gate structure 222 in the second direction D2 may be the same as the width of the second upper channel layer 221 in the second direction D2. A side surface of a lower part of the insulating material E filling the removed portion in the second upper gate structure 222 may be in contact with the upper source/drain structure 81 adjacent to the second upper gate structure 222. A portion of the bottom surface of the insulating material E filling the removed portion in the second upper gate structure 222 may be in contact with the second upper gate structure 222.

The length of the second upper gate contact 922 in the third direction D3 may be greater than the length of the first upper gate contact 921 in the third direction D3 and the length of the third upper gate contact 923 in the third direction D3. The second upper gate contact 922 may be connected to the second upper gate structure 222 by penetrating the insulating material E filling the removed portion in the second upper gate structure 222. The bottom surface of the second upper gate contact 922 may be formed at a position that is lower than a position of the lowermost surface of the interlayer dielectric B.

A width of the second upper gate contact 922 in the second direction D2 may be less than the width of the insulating material E filling the removed portion in the second upper gate structure 222 in the second direction D2. A width of a bottom surface of the second upper gate contact 922 in contact with the second upper gate structure 222 in the second direction D2 may be less than or equal to the width of the second upper gate structure 222 in the second direction D2.

A width of the insulating material E filling the portion removed by the second slit in the third lower gate structure 312 in the second direction D2 may be the same as the width of the third lower channel layer 311 in the second direction D2. The side surface of the upper part of the insulating material E filling the removed portion in the third lower gate structure 312 may be in contact with the lower source/drain structure 82 adjacent to the third lower gate structure 312. A portion of the top surface of the insulating material E filling the removed portion in the third lower gate structure 312 may be in contact with the third lower gate structure 312.

The length of the third lower gate contact 943 in the third direction D3 may be greater than the length of the first lower gate contact 941 in the third direction D3 and the length of the second lower gate contact 942 in the third direction D3. The third lower gate contact 943 may be connected to the third lower gate structure 312 by penetrating the insulating material E filling the removed portion in the third lower gate structure 312. The top surface of the third lower gate contact 943 may be formed at a position that is higher than a position of the uppermost surface of the substrate A.

A width of the third lower gate contact 943 in the second direction D2 may be less than the width of the insulating material E filling the removed portion in the third lower gate structure 312 in the second direction D2. A width of a top surface of the third lower gate contact 943 in contact with the third lower gate structure 312 in the second direction D2 may be less than or equal to the width of the third lower gate structure 312 in the second direction D2.

Some of the processes described above may be replaced with a process according to a modified embodiment described below.

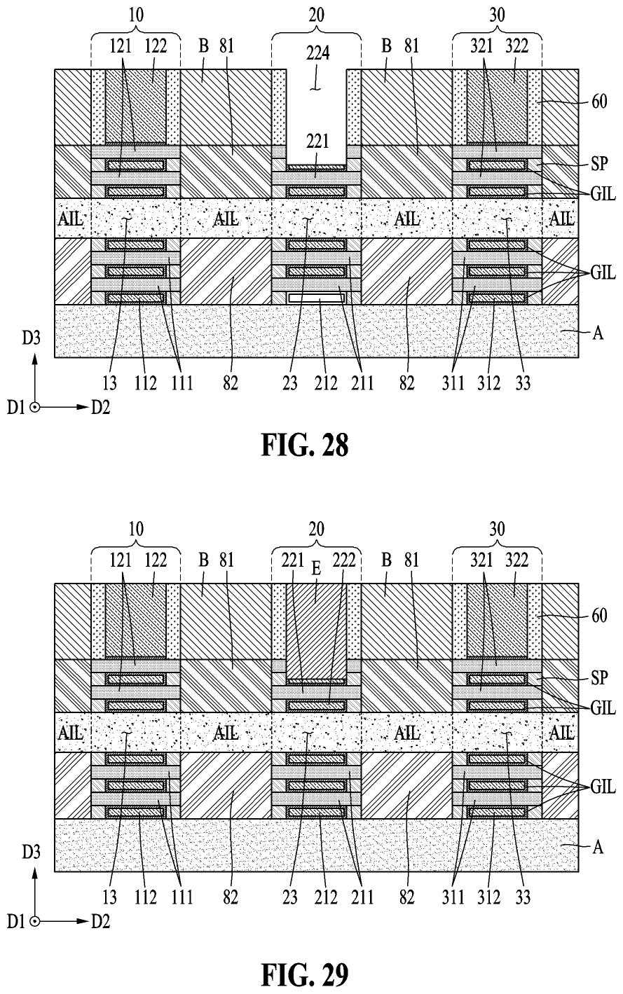

FIGS. 28 to 31 illustrate a portion of a manufacturing process of a semiconductor device according to another example embodiment.

The processes according to FIGS. 17 and 18 may be replaced with the processes according to FIGS. 28 and 29.

Referring to FIG. 28, the first slit 224 that removes a portion of the second upper gate structure 222 of the second transistor stack 20 may be formed by an etching process. The gate spacers 60 disposed on both sides of the second upper gate structure 222 may be maintained and the first slit 224 may be formed between the gate spacers 60. A portion of the second upper channel layer disposed on the uppermost end of the second upper gate structure 222 may be removed by the first slit 224. In other words, the second upper channel layer disposed on the uppermost end of the second upper gate structure 222 may not be completely removed by the first slit 224, and the other portion of the second upper channel layer disposed on the uppermost end of the second upper gate structure 222 may remain. For example, a central portion of the second upper channel layer disposed on the uppermost end of the second upper gate structure 222 may be completely removed by the first slit 224, and both side areas of the second upper channel layer disposed on the uppermost end of the second upper gate structure 222 may remain. The both side areas of the second upper channel layer disposed on the uppermost end of the second upper gate structure 222 may be an area adjacent to the upper source/drain structure 81.

Referring to FIG. 29, the portion removed by the first slit may be filled with the insulating material E. The insulating material E may be formed of the same material as the interlayer dielectric B. The bottom surface of the insulating material E may be in contact with a portion of the second upper gate structure 222 in the third direction D3. The side surface of the upper part of the insulating material E may be in contact with the remaining gate spacer 60 in the second direction D2. The side surface of the lower part of the insulating material E may be in contact with the remaining internal spacer SP or the other portion of the second upper channel layer disposed on the uppermost end of the second upper gate structure 222 in the second direction D2.

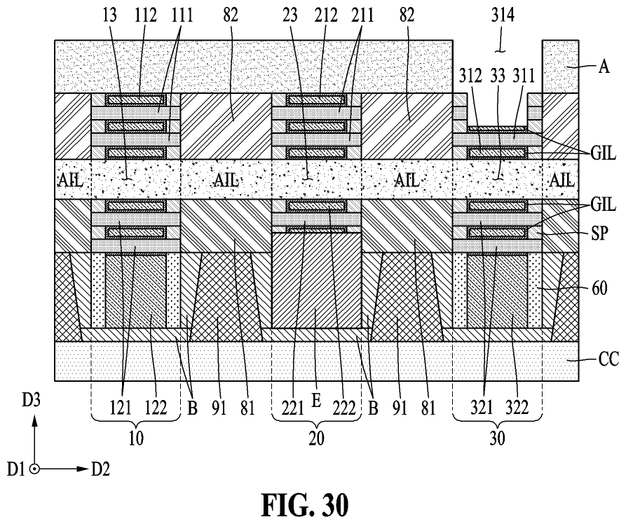

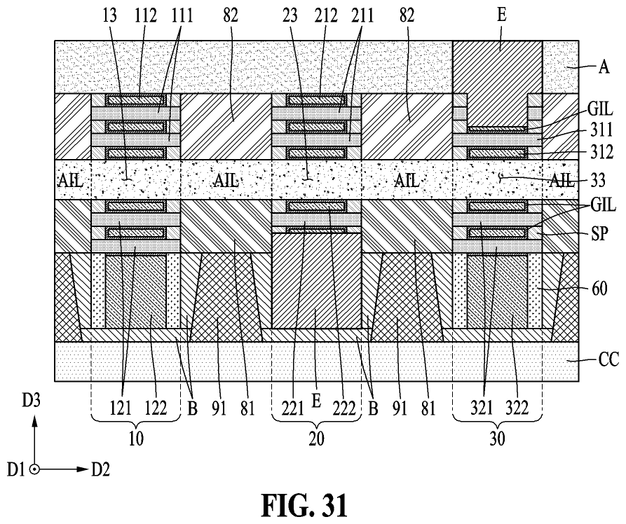

The processes according to FIGS. 23 and 24 may be replaced with the processes according to FIGS. 30 and 31.

Referring to FIG. 30, the second slit 314 that removes a portion of the third lower gate structure 312 of the third transistor stack 30 and the substrate A may be formed by an etching process. A portion of the third lower channel layer in the third lower gate structure 312 disposed closest to the substrate A may be removed by the second slit 314. In other words, the third lower channel layer in the third lower gate structure 312 disposed closest to the substrate A may not be completely removed by the second slit 314, and the other portion of the third lower channel layer in the third lower gate structure 312 disposed closest to the substrate A may remain. For example, a central portion of the third lower channel layer in the third lower gate structure 312 disposed closest to the substrate A may be completely removed by the second slit 314, and both side areas of the third lower channel layer in the third lower gate structure 312 disposed closest to the substrate A may remain. The both side areas of the third lower channel layer in the third lower gate structure 312 disposed closest to the substrate A may be an area adjacent to the lower source/drain structure 82.

Referring to FIG. 31, the portion removed by the second slit may be filled with the insulating material E. The insulating material E may be formed of the same material as the interlayer dielectric B. One surface of the insulating material E disposed closest to the additional intermediate insulating layer AIL may be in contact with a portion of the third lower gate structure 312 in the third direction D3. The side surface of the insulating material E may be in contact with the remaining substrate A in the second direction D2, the internal spacer SP, or the other portion of the third lower channel layer in the third lower gate structure 312 disposed closest to the substrate A.

Among the processes of manufacturing the semiconductor device according to FIGS. 8 to 27, only the processes according to FIGS. 17 and 18 may be replaced with the processes according to FIGS. 28 and 29.

Among the processes of manufacturing the semiconductor device according to FIGS. 8 to 27, only the processes according to FIGS. 23 and 24 may be replaced with the processes according to FIGS. 30 and 31.

Among the processes of manufacturing the semiconductor device according to FIGS. 8 to 27, the processes according to FIGS. 17 and 18 may be replaced with the processes according to FIGS. 28 and 29, and the processes according to FIGS. 23 and 24 may be replaced with the processes according to FIGS. 30 and 31.

The process described above may be similarly applied to the manufacturing of another semiconductor device having a different combination of the number of channel layers.

As described above, the semiconductor device and the method of manufacturing the semiconductor device according to the present disclosure may implement an optimal performance or optimal speed for each individual transistor stack by including a plurality of transistor stacks configuring the semiconductor device and varying sums of the numbers of channel layers disposed in each transistor stack to be different from each other.

In addition, the semiconductor device and the method of manufacturing the semiconductor device according to the present disclosure may implement an optimal performance or optimal speed by setting the number of channel layers disposed in the transistor differently to suit the characteristics of an element for each individual transistor stack configuring the semiconductor device.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. For example, suitable results may be achieved if the described techniques are performed in a different order and/or if components in a described system, architecture, device, or circuit are combined in a different manner and/or replaced or supplemented by other components or their equivalents.

What is claimed is:

1. A semiconductor device comprising:
a substrate; and
a plurality of transistor stacks formed on the substrate,
wherein each of the transistor stacks comprises:
a lower transistor comprising at least one lower channel layer and a lower gate structure enclosing the at least one lower channel layer and formed on the substrate; and
an upper transistor comprising at least one upper channel layer and an upper gate structure enclosing the at least one upper channel layer and formed on the lower transistor,
wherein a sum of a number of first lower channel layers and a number of first upper channel layers of a first transistor stack is different from a sum of a number of second lower channel layers and a number of second upper channel layers of a second transistor stack.

2. The semiconductor device of claim 1, wherein the number of the first lower channel layers is the same as the number of the second lower channel layers, and the number of the first upper channel layers is different from the number of the second upper channel layers.

3. The semiconductor device of claim 1, wherein the number of the first upper channel layers is the same as the number of the second upper channel layers, and the number of the first lower channel layers is different from the number of the second lower channel layers.

4. The semiconductor device of claim 1, wherein the sum of the number of the first lower channel layers and the number of the first upper channel layers of the first transistor stack is greater than the sum of the number of the second lower channel layers and the number of the second upper channel layers of the second transistor stack.

5. The semiconductor device of claim 4, further comprising:
a third transistor stack,
wherein a sum of a number of third lower channel layers and a number of third upper channel layers of the third transistor stack is the same as the sum of the number of the second lower channel layers and the number of the second upper channel layers of the second transistor stack.

6. The semiconductor device of claim 5, wherein the number of the third upper channel layers is different from the number of the second upper channel layers and the number of the third lower channel layers is different from the number of the second lower channel layers.

7. The semiconductor device of claim 6,
wherein a second upper transistor of the second transistor stack comprises a first slit that removes a portion of a second upper gate structure,
wherein a third lower transistor of the third transistor stack comprises a second slit that removes a portion of a third lower gate structure, and
wherein a portion of channel layers disposed in a gate structure is removed by the first slit or the second slit.

8. The semiconductor device of claim 7,
wherein the number of the second upper channel layers is one and the number of the second lower channel layers is two, and
wherein the number of the third upper channel layers is two and the number of the third lower channel layers is one.

9. The semiconductor device of claim 8, wherein an inside of the first slit or the second slit is filled with an insulating material.

10. The semiconductor device of claim 5, wherein a width of a channel layer of the first transistor stack, a width of a channel layer of the second transistor stack, and a width of a channel layer of the third transistor stack are the same as or different from each other.

11. The semiconductor device of claim 5,
wherein upper transistors of the first transistor stack, the second transistor stack, and the third transistor stack are n-channel metal oxide semiconductor (NMOS) transistors, and
wherein lower transistors of the first transistor stack, the second transistor stack, and the third transistor stack are p-channel metal oxide semiconductor (PMOS) transistors.

12. The semiconductor device of claim 5, further comprising:
a plurality of lower source/drain structures respectively disposed on both ends of the lower transistors of the first transistor stack, the second transistor stack, and the third transistor stack; and
a plurality of upper source/drain structures respectively disposed on both ends of the upper transistors of the first transistor stack, the second transistor stack, and the third transistor stack.

13. The semiconductor device of claim 7,
wherein the number of the second upper channel layers is one and the number of the second lower channel layers is three, and
wherein the number of the third upper channel layers is three and the number of the third lower channel layers is one.

14. The semiconductor device of claim 7,
wherein the number of the second upper channel layers is two and the number of the second lower channel layers is three, and
wherein the number of the third upper channel layers is three and the number of the third lower channel layers is two.

15. The semiconductor device of claim 7,
wherein the number of the second upper channel layers is two and the number of the second lower channel layers is four, and
wherein the number of the third upper channel layers is four and the number of the third lower channel layers is two.

16. A method of manufacturing a semiconductor device, the method comprising:
forming a plurality of transistor stacks comprising a lower transistor comprising at least one lower channel layer and a lower gate structure enclosing the at least one lower channel layer and an upper transistor comprising at least one upper channel layer and an upper gate structure enclosing the at least one upper channel layer;
forming an upper source/drain structure or a lower source/drain structure between the transistor stacks spaced apart from each other;
forming a first slit that removes a portion of a second upper gate structure of a second upper transistor of a second transistor stack;
filling an inside of the first slit with an insulating material; and
forming a gate contact or a source/drain contact respectively connected to the upper gate structure or the upper source/drain structure.

17. The method of claim 16, wherein the forming of the first slit comprises:
removing a portion of channel layers disposed in the second upper gate structure by the first slit.

18. The method of claim 17, further comprising:
disposing a carrier on a top surface of the plurality of transistor stacks;
flipping the plurality of transistor stacks;
forming a second slit that removes a portion of a third lower gate structure of a third lower transistor of a third transistor stack;
filling an inside of the second slit with an insulating material; and
forming a gate contact or a source/drain contact respectively connected to the lower gate structure or the lower source/drain structure.

19. The method of claim 18, wherein the forming of the second slit comprises:
removing a portion of channel layers disposed in the third lower gate structure by the second slit.

20. The method of claim 19, further comprising:
flipping the plurality of transistor stacks again; and
removing the carrier disposed on the top surface of the plurality of transistor stacks.
